(19) United States
(12) Patent Application Publication
(10) Pub. No.: US 2026/0236655 A1
(43) Pub. Date: Aug. 13, 2026

(54) INFORMATION PROCESSING APPARATUS AND INFORMATION PROCESSING METHOD

(71) Applicant: Kioxia Corporation, Tokyo (JP)

(72) Inventor: Satoru YOKOTA, Yokohama Kanagawa (JP)

(73) Assignee: Kioxia Corporation, Tokyo (JP)

(21) Appl. No.: 19/308,566

(22) Filed: Aug. 25, 2025

(30) Foreign Application Priority Data
Feb. 10, 2025 (JP) 2025-020119

(51) Int. Cl. G06F 30/3308; G06F 30/27

(52) U.S. Cl. CPC G06F 30/3308; G06F 30/27

(57) ABSTRACT

An information processing apparatus includes processing circuitry configured to execute simulation based on a simulation model, manage a variation in parameter set in the simulation model, learn a prediction model by performing regression learning based on a relationship between the parameter and a simulation execution result, calculate robustness based on a prediction model learning result and the variation in parameter; and optimize the robustness based on the calculated robustness, the prediction model, and the parameter.

### CROSS REFERENCE TO RELATED APPLICATIONS

This application is based upon and claims the benefit of priority from the prior Japanese Patent Application No. 2025-020119, filed on Feb. 10, 2025, the entire contents of which are incorporated herein by reference.

### FIELD

An embodiment described herein relates to an information processing apparatus and an information processing method.

### BACKGROUND

As semiconductor miniaturization progresses, semiconductor defects are more likely to occur, and therefore it is required to efficiently find manufacturing conditions capable of improving the yield. Recently, a simulation model is used for evaluation of a semiconductor. In order to perform simulation using a simulation model, it is necessary to input various parameters according to the manufacturing conditions to the simulation model.

However, since actual manufacturing conditions vary due to various factors, it is desirable to perform simulation in consideration of a variation in parameter.

### BRIEF DESCRIPTION OF THE DRAWINGS

FIG. 1 is a block diagram illustrating a schematic configuration of an information processing apparatus according to an embodiment.

FIGS. 2A, 2B and 2C are cross-sectional diagrams illustrating variations in forming portion of a void.

FIG. 3 is a diagram for explaining a clear rate.

FIG. 4 is a diagram illustrating an example of a curve of a simulation execution result that has been sigmoid-converted using a sigmoid function.

FIG. 5 is a diagram for explaining a variation in parameter.

FIG. 6 is a diagram illustrating a curve of a specification excess amount indicated in Formula (6).

FIG. 7 is a flowchart illustrating a processing operation of the information processing apparatus according to the present embodiment.

FIG. 8 is a flowchart in which step S12 is added between steps S6 and S7 in FIG. 7.

FIG. 9 is a diagram illustrating a data configuration stored in a storage unit of the information processing apparatus.

FIG. 10 is a diagram illustrating an example of an acquisition function representing robustness.

FIG. 11 is a diagram for explaining a processing operation of an optimization start point determination unit.

FIG. 12 is a flowchart illustrating a processing procedure of an optimization execution unit.

FIGS. 13A and 13B are diagrams for explaining processing of the optimization execution unit.

FIG. 14 is a flowchart illustrating a processing procedure of steps S32 to S34 of FIG. 12 in more detail.

FIG. 15 is a diagram for explaining the processing of the flowchart of FIG. 14.

FIG. 16 is a diagram illustrating a curve of erfc(−z)/2.

FIG. 17 is a diagram illustrating a state in which a peak is collapsed.

### DETAILED DESCRIPTION

An information processing apparatus according to an embodiment includes: processing circuitry configured to:
execute simulation based on a simulation model;
manage a variation in parameter set in the simulation model;
learn a prediction model by performing regression learning based on a relationship between the parameter and a simulation execution result;
calculate robustness based on a prediction model learning result and the variation in parameter; and
optimize the robustness based on the calculated robustness, the prediction model, and the parameter.

Hereinafter, an embodiment of an information processing apparatus and an information processing method will be described with reference to the drawings. Although main components of the information processing apparatus will be mainly described below, the information processing apparatus may have components and functions that are not illustrated or described. The following description does not exclude components and functions that are not illustrated or described.

### (Configuration of Information Processing Apparatus)

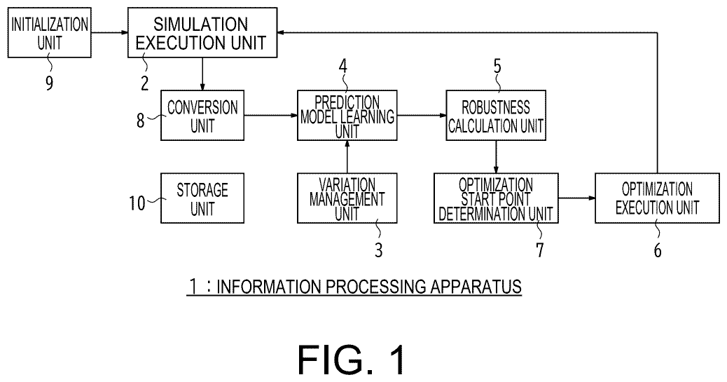

FIG. 1 is a block diagram illustrating a schematic configuration of an information processing apparatus 1 according to an embodiment. The information processing apparatus 1 illustrated in FIG. 1 includes, for example, a general-purpose computer, a central processing unit (CPU), or the like. As will be described later, at least some functions of the information processing apparatus 1 according to the embodiment can be implemented by hardware or software. In a case where at least some functions of the information processing apparatus 1 are implemented by software, the functions of the information processing apparatus 1 can be implemented by a computer or a CPU executing a program. Hereinafter, the computer or the CPU may be called as processing circuitry.

As illustrated in FIG. 1, the information processing apparatus 1 according to the embodiment includes a simulation execution unit 2, a variation management unit 3, a prediction model learning unit 4, a robustness calculation unit 5, and an optimization execution unit 6.

The simulation execution unit 2 executes simulation based on a simulation model. The simulation model is, for example, a model for simulating at least one of a structure or a characteristic of a semiconductor device. Various parameters are input to the simulation model. The parameters are, for example, various types of information regarding manufacturing conditions of the semiconductor device. The manufacturing conditions include, for example, information on a shape, a size, a constituent material, a temperature at the time of manufacturing, a humidity, a degree of vacuum, a material used at the time of manufacturing, and the like of the semiconductor device. Although a plurality of parameters are input to the simulation model, they are simply referred to as “parameter” in the present specification.

The variation management unit 3 manages a variation in parameter set in the simulation model. For example, assuming that the variation in parameter is represented by a normal distribution, the variation management unit 3 gives a variation to the parameter within a range of a standard deviation σ×±m (m is a real number of 1 or more) times of the normal distribution. The value of m is determined based on a proportion of the parameter existing within the above-described range of the normal distribution. Specifically, the variation management unit 3 can give a variation to the parameter based on a variation function X=g(x).

The prediction model learning unit 4 learns a prediction model by performing regression learning based on a relationship between a parameter and a simulation execution result. The prediction model is a model that predicts a simulation execution result. For example, the prediction model learning unit 4 learns the prediction model based on the parameter to which a variation is given within the range of the standard deviation σ×±m times of the normal distribution. A specific example of the prediction model will be described later.

The robustness calculation unit 5 calculates robustness based on a prediction model learning result and a variation in parameter managed by the variation management unit 3. The robustness includes at least one of a proportion of a prediction model learning result satisfying a specification, an excess amount of the prediction model learning result from a specification (hereinafter, specification excess amount), a maximum value of the prediction model learning result caused by the variation in parameter, an average value of the prediction model learning results caused by the variation in parameter, or a difference between the maximum value and the average value described above. In the present specification, the specification may be referred to as a target range.

The robustness calculation unit 5 may calculate the robustness based on a variation function calculated by the variation management unit 3 and a prediction distribution of the simulation execution results. Alternatively, the robustness calculation unit 5 may calculate the robustness based on the variation function calculated by the variation management unit 3 and a prediction average of the simulation execution results.

The optimization execution unit 6 optimizes the robustness based on the calculated robustness, the prediction model, and the parameter.

The information processing apparatus 1 according to the embodiment may include an optimization start point determination unit 7. The optimization start point determination unit 7 determines a position of a start point for optimizing robustness set on a curve representing robustness calculated by the robustness calculation unit 5. In this case, the optimization execution unit 6 searches for an optimum point of robustness on the curve representing robustness with the start point as a starting point.

For example, the optimization start point determination unit 7 may determine a random search on the curve representing robustness, classification using a decision tree, a maximum improvement point of robustness, or a median value of a search range as the start point for optimization. More specifically, the optimization start point determination unit 7 may classify a two-dimensional space indicating a relationship between the parameter and the robustness into a plurality of regions using a decision tree, compare the number of satisfaction of the robustness satisfying the target range in each of the plurality of regions, and determine the start point from a region having a maximum number of satisfaction.

In addition, the optimization start point determination unit 7 may determine the start point for optimization on a curve of a first robustness calculation function calculated based on the variation function calculated by the variation management unit 3 and the prediction distribution of the simulation execution results.

Alternatively, the optimization start point determination unit 7 may determine the start point for optimization on a curve of a second robustness calculation function calculated based on the variation function calculated by the variation management unit 3 and the prediction average of the simulation execution results.

In addition, the optimization start point determination unit 7 may assume that the variation in parameter is represented by a normal distribution, and may determine, as the start point, a point at which a simulation execution result in a case where the optimum point of the curve representing robustness is set as a center of the normal distribution is maximized or minimized.

The optimization execution unit 6 may search for an optimum point that optimizes the robustness by repeating processing of setting a first additional start point and a second additional start point on both sides with the start point interposed therebetween on the curve representing robustness, and newly setting the first additional start point and the second additional start point on both sides of a new start point obtained by optimizing the robustness based on the start point, the first additional start point, and the second additional start point.

In addition, the optimization execution unit 6 may search for the optimum point by repeating processing of performing a shape change of a curve for giving a penalty to the start point when the first additional start point and the second additional start point located on both sides with the start point interposed therebetween are set on the curve representing robustness, and setting a new start point, a new first additional start point, and a new second additional start point with respect to the curve after the shape change.

Note that, as will be described later, it is also possible to optimize the robustness without using the start point, and the optimization start point determination unit 7 is not an essential configuration block.

The information processing apparatus 1 according to the embodiment may include a conversion unit 8. The conversion unit 8 converts the simulation execution result in accordance with a predetermined specification. In this case, the prediction model learning unit 4 learns the prediction model based on the parameter and the simulation execution result converted by the conversion unit 8.

For example, the conversion unit 8 sigmoid-converts the simulation execution result based on a specification and a sigmoid function. The conversion unit 8 sigmoid-converts the simulation execution result so that the simulation execution result closer to the specification changes more greatly. In this case, the prediction model learning unit 4 learns the prediction model by performing regression learning based on the parameter and the simulation execution result that has been sigmoid-converted. More specifically, the prediction model learning unit 4 performs Gaussian process regression based on the parameter and the simulation execution result that has been sigmoid-converted, and updates a prediction average function and a prediction distribution configuring the prediction model.

The information processing apparatus 1 according to the embodiment may include an initialization unit 9. The initialization unit 9 generates a parameter x to be input to the simulation model by using a random number. Alternatively, the initialization unit 9 may read out the parameter x stored in advance in the storage unit 10.

The information processing apparatus 1 according to the embodiment may include a storage unit 10 that stores information such as a processing result of each block illustrated in FIG. 1. Although these pieces of information may be divided and stored in a plurality of storage units 10, an example in which a processing result or the like of each block is stored in association with one storage unit 10 will be described below.

### (Prediction Model)

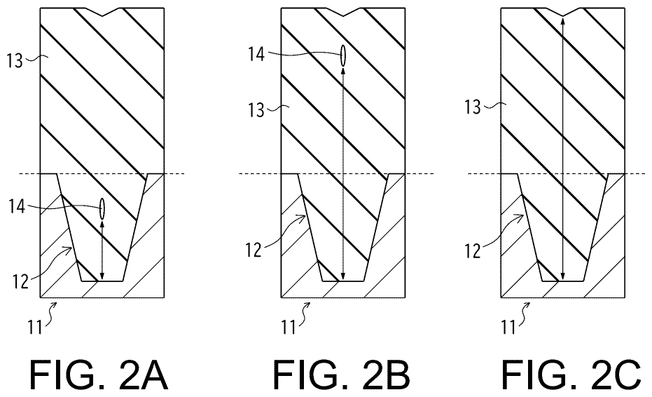

In a manufacturing process of filling an oxide layer inside a narrow trench formed in a part of a semiconductor device, it is difficult to fill a uniform oxide layer, and voids may be generated in a part. FIGS. 2A, 2B, and 2C are cross-sectional diagrams illustrating variations in forming portion of a void 14. FIG. 2A illustrates an example in which the void 14 is formed inside a trench 12, FIG. 2B illustrates an example in which the void 14 is formed above the trench 12, and FIG. 2C illustrates an example in which the void 14 is not formed.

It is assumed that there is a process of removing an oxide layer 13 in accordance with an upper surface (broken line) of the trench 12 after the process illustrated in FIGS. 2A, 2B and 2C. In this case, it is best not to form the void 14 in the oxide layer 13 as illustrated in FIG. 2C, but even when the void 14 is formed above the trench 12 as illustrated in FIG. 2B, this void 14 is finally removed, and thus is not regarded as a defect.

In a simulation model for analyzing defects as illustrated in FIG. 2A, a height from a bottom surface of the trench 12 to the void 14 can be used as a simulation execution result. In this case, as illustrated in FIG. 2C, when the void 14 does not exist, the simulation execution result is the height from the bottom surface of the trench 12 to the upper surface of the oxide layer 13. In the present specification, when the height of the void 14 is less than the height from the bottom surface to the upper surface of the trench 12, it is determined that a specification is not satisfied, and when the height of the void 14 is higher than the upper surface of the trench 12, it is determined that a specification is satisfied. In the present specification, a clear rate is provided as an index for determining whether a specification is satisfied.

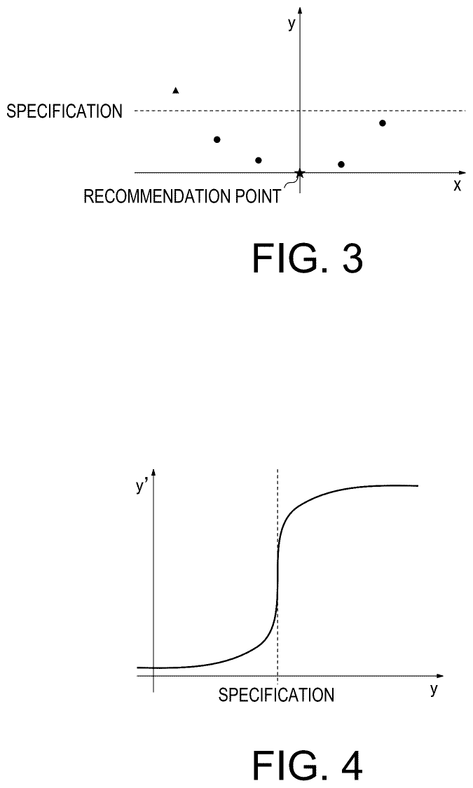

FIG. 3 is a diagram for explaining a clear rate. FIG. 3 illustrates an example in which there are six samples, five of which satisfy a specification indicated by a broken line, and the remaining one does not satisfy a specification. The clear rate is a value obtained by dividing the number of samples satisfying the specification (sometimes referred to as a clear number) by the total number of samples. In the case of FIG. 3, the clear rate=5/6. This clear rate can be used as a simulation execution result.

The information processing apparatus 1 according to the present embodiment has in mind that a solution (parameter) having a clear rate of 100%, which is a simulation execution result, is found at high speed even when a variation is given to the parameter.

In the present embodiment, a reciprocal of the height of the void 14 described above is set as an output of the prediction model. As a result, the smaller the output value of the prediction model is, the more desirable it is.

### (Sigmoid Conversion)

When a prediction accuracy of the simulation execution result is low, it is difficult to correctly predict a solution in which the above-described clear rate equals 100%. When it is determined whether the simulation execution result satisfies the specification, it is desirable to further improve a determination accuracy in the vicinity of a boundary of the specification. Therefore, in the present embodiment, in order to further emphasize the prediction model in the vicinity of the boundary of the specification, the conversion unit 8 sigmoid-converts the simulation execution result.

FIG. 4 is a diagram illustrating an example of a curve of a simulation execution result that has been sigmoid-converted using a sigmoid function. In FIG. 4, a horizontal axis represents a simulation execution result y before sigmoid conversion, a vertical axis represents a simulation execution result y′ after sigmoid conversion, and a broken line represents a specification. As illustrated in FIG. 4, by performing the sigmoid conversion, the simulation execution result y′ can be changed more greatly in the vicinity of the specification, and accordingly, it is possible to intensively learn an important portion when predicting the clear rate.

### (Generation of Variation in Parameter)

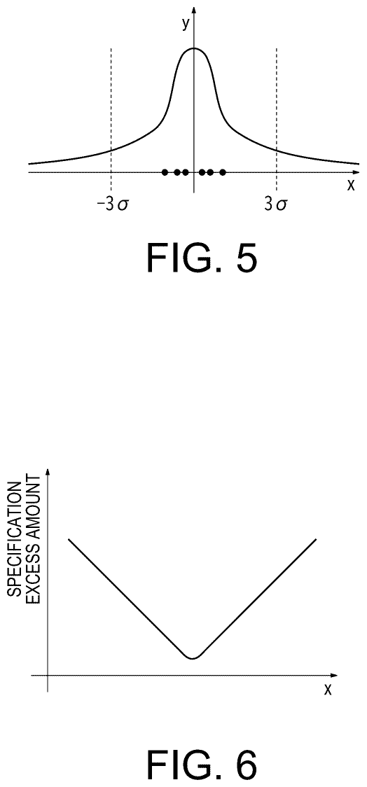

As described above, a plurality of parameters are input to the simulation model. Values of the standard deviations σ of the parameters are not necessarily the same, and the variation distribution of the parameters is different. A multidimensional normal distribution ND(x, Σ) of a mean vector x of the parameter and a variance-covariance matrix Σ is represented by, for example, a curve as illustrated in FIG. 5. The variance-covariance matrix Σ is represented by Formula (1). As indicated in Formula (1), the variance-covariance matrix Σ is a diagonal matrix having a standard deviation σj of each dimension j as a diagonal component.

$$Variance - covariance matrix \sum = [ \begin{matrix}σ {1}^{2} & … & 0 \\ ⋮ & ⋱ & ⋮ \\ 0 & … & σ {D}^{2}\end{matrix} ] \qquad ( 1 )$$

The variation management unit 3 gives a variation within the range of the standard deviation σ×±m (m is an integer of 1 or more, for example, m=3) from a center value of the multidimensional normal distribution ND(x,Σ) in FIG. 5 to each parameter. As a result, the prediction model learning unit 4 can learn the prediction model in consideration of the variation for each parameter.

First to third methods can be considered as a method in which the variation management unit 3 manages the variation in each parameter. The first method is a method of giving a variation to each parameter by using a normal distribution designated by a user. An output X of the variation management unit 3 in this case is represented by the following Formula (2). Each element xi of the output X has a variation represented by a normal distribution of an average value μ and a standard deviation Σ.

$$X = [ x 1 , … , xi , … , and xp ] , where xi = N ( μ , \sum ) \qquad ( 2 )$$

In the first method, there is a possibility that the variation is underestimated, and a large number of samples are required to perform strict evaluation, and thus the calculation cost is high.

The second method is a method of giving a variation to each parameter using only a normal distribution at the σ level. A normal distribution Σ′ at the σ level is represented by the following Formula (3).

$${\sum }^{′} = {k}^{2} \sum , where k > 0 \qquad ( 3 )$$

A matrix X′ that is the output of the variation management unit 3 is represented by the following Formula (4).

$${X}^{′} = [ μ + \frac{{X}_{1}^{′}}{\sqrt{{X}_{1}^{′} {\sum }^{′ - 1} {X}_{1}^{′ T}}} , … , μ + \frac{{X}_{j}^{′}}{\sqrt{{X}_{j}^{′} {\sum }^{′ - 1} {X}_{j}^{′ T}}} , … , μ + \frac{{X}_{q}^{′}}{\sqrt{{X}_{q}^{′} {\sum }^{′ - 1} {X}_{q}^{′ T}}} ] \qquad ( 4 )$$

$$where {X}_{j}^{′} ∼ N ( 0 , {\sum }^{′} )$$

where, the fraction in each term on the right side of equation (4) represents element-wise division by the square root, and T denotes the transpose. N(0, Σ′) represents a multivariate Gaussian distribution with a mean vector of 0 and a variance-covariance matrix of Σ′. The notation x′ⱼ~N(0, Σ′) indicates that, for example, in the case where N(0, Σ′) is a two-dimensional Gaussian distribution, x′ⱼ refers to a sampled two-dimensional vector.

In the second method, even when the parameter varies in the early stage of the learning of the prediction model, there is a possibility that a difference does not occur in a solution, and the solution fits into a local solution by a gradient method.

The third method is a method adopted by the present embodiment, and is a method of giving a variation to each parameter by using a normal distribution and a normal distribution at the σ level in combination. An output Xaccelerator of the variation management unit 3 in the third method is represented by the following Formula (5).

$$Xaccelerator = [ x 1 , … , xi , … , xp , {x}^{′} 1 , … , {x}^{′} j , … , and {x}^{′} q ] \qquad ( 5 )$$

For a small number of samples, a variation is given to the parameter within a specified range of σ to evaluate the robustness. A magnitude of the variation in parameter can be adjusted by adjusting a ratio of q to p and adjusting the value of m multiplied by σ according to a magnitude of a predicted clear rate.

### (Calculation of Specification Excess Amount)

In a case where a relationship between the parameter x and the clear rate is calculated as robustness, the clear rate hardly changes even when the parameter x is slightly changed with the variation. Therefore, the relationship between the parameter x and the clear rate becomes a flat relationship, and it becomes difficult to maximize the clear rate by using the gradient method.

Therefore, in the present embodiment, the specification excess amount represented by the following Formula (6) is calculated as robustness.

$$Specificaton excess amount = {\sum }_{i = 1}^{n} \{ max ( {y}_{i} , {θ}_{spec} ) - {θ}_{spec} \} \qquad ( 6 )$$

In the present specification, the specification excess amount of Formula (6) may be referred to as a proxy embedding clear rate.

FIG. 6 is a diagram illustrating a curve of the specification excess amount indicated in Formula (6). In FIG. 6, a horizontal axis represents a parameter, and a vertical axis represents a specification excess amount. As can be seen from a curve in FIG. 6, when max(yi, θspec)=yi, the specification excess amount is represented by yi−θspec, and yi−θspec is a continuous value, so that it is difficult to be flat.

A specific example of the calculation of the specification excess amount will be described below. A variation around a certain parameter x=0 is considered. It is assumed that the specification is 1. It is assumed that the parameter x is represented by Formula (7) and the simulation execution result y is represented by Formula (8).

$$x = [ 3 , 2 , 1 , 0 , 1 , 2 ] \qquad ( 7 )$$

$$y = [ 1.1 , 0.7 , 0.5 , 0.1 , 0.3 , 0.8 ] \qquad ( 8 )$$

The specification excess amount in this example is represented by the above-described Formula (6).

In Formula (6), max(yi, θspec) is compared with θspec, and the larger one is selected. For example, max(0.5, 1)=1 and max(1.3, 1)=1.3.

When the parameter x is represented by Formula (7) and the simulation execution result y is represented by Formula (8), the specification excess amount is represented by the following Formula (9).

$$Specification excess amount = {\sum }_{i = 1}^{6} \{ max ( {y}_{i} , 1 ) - 1 \} \qquad ( 9 )$$

The right side of Formula (9) is transformed as Formula (10) below.

$$Specification excess amount = max ( 1.1 , 1 ) - 1 + max ( 0.7 , 1 ) - 1 + max ( 0.5 , 1 ) - 1 + max ( 0.1 , 1 ) - 1 + max ( 0.3 , 1 ) - 1 + max ( 0.8 , 1 ) - 1 = 0.1 + 0 + 0 + 0 + 0 + 0 \qquad ( 10 )$$

The specification excess amount indicated in Formula (6) holds not only a binary distinction of whether the specification is satisfied, but also information on how much the specification is exceeded.

In addition, the specification excess amount is an index in which a change amount with respect to a slight change in the parameter x is large. Therefore, by using the specification excess amount instead of the clear rate, the relationship between the parameter x and the clear rate does not become flat, and it is possible to avoid a situation in which it is difficult to maximize the clear rate using the gradient method when the relationship between the parameter x and the clear rate is flat.

Since the specification can be guaranteed by 100% when the specification excess amount is zero, minimizing the specification excess amount can be used as a proxy for the purpose of maximizing the clear rate.

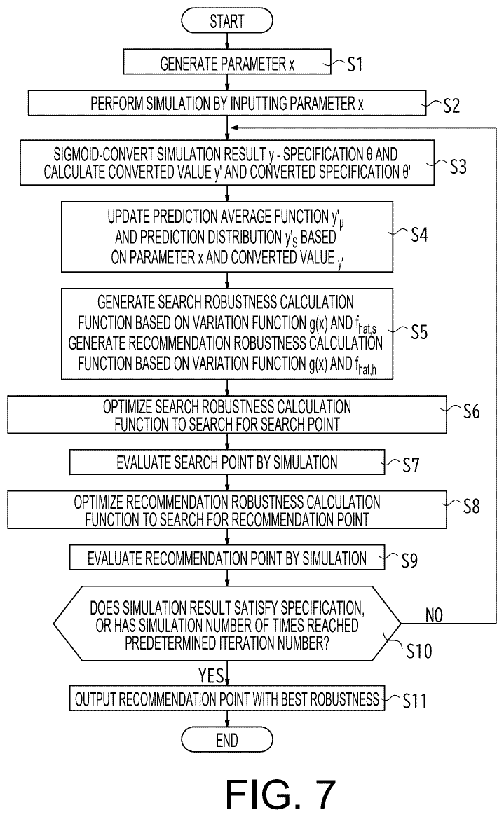

FIG. 7 is a flowchart illustrating a processing operation of the information processing apparatus 1 according to the present embodiment. First, the initialization unit 9 generates the parameter x by using, for example, a random number (step S1). The generated parameter x is input to the simulation model. Note that the simulation model is read out from the storage unit 10 to the simulation execution unit 2, for example.

Next, the simulation execution unit 2 executes simulation by using the simulation model and stores a simulation execution result in the storage unit 10 (step S2).

Note that the processing in steps S1 and S2 may be performed by a device other than the information processing apparatus 1. In this case, the information processing apparatus 1 may read out the execution result of the simulation performed by the device.

Next, the conversion unit 8 calculates a converted value y′ obtained by sigmoid-converting the difference (y−θspec) between the simulation execution result y and the specification θspec and a specification θ′ obtained by sigmoid conversion (step S3). The converted value y′ is represented by the following Formula (11), and the specification θ′ is represented by the following Formula (12).

$${y}^{′} = \frac{1}{1 + {e}^{- ( y - θ )}} \qquad ( 11 )$$

$${θ}^{′} = \frac{1}{1 + {e}^{- ( θ - θ )}} = \frac{1}{2} \qquad ( 12 )$$

Next, the prediction model learning unit 4 performs Gaussian process regression based on a set of the parameter x and the converted value y′ of the simulation execution result to update the prediction average function and the prediction distribution configuring the prediction model (step S4).

A prediction average function y′μ is represented by Formula (13), and a prediction distribution y's is represented by Formula (14).

$${y}^{′} μ = fhat , m ( x ) \qquad ( 13 )$$

$${y}^{′} s = fhat , s ( x ) \qquad ( 14 )$$

Next, the robustness calculation unit 5 generates a search robustness calculation function hs(fhat,s(g(x))) for calculating robustness based on the variation function X=g(x) calculated by the variation management unit 3 and the prediction distribution fhat,s. In addition, the robustness calculation unit 5 generates a recommendation robustness calculation function hr(fhat,m(g(x))) for calculating robustness based on the variation function X=g(x) calculated by the variation management unit 3 and the prediction distribution fhat,s(step S5).

Hereinafter, a specific example of the processing of step S5 will be described. Hereinafter, an example of calculating robustness of a certain parameter x will be described. A set of variations {xi}(i=1, . . . , and M) in the parameter x is generated based on the variation function X=g(x). The set of variations is sampled from the variation distribution of the variation function.

Next, a set of predicted values {yi}(i=1, . . . , and M) of the simulation execution result y is calculated with the prediction average or the prediction distribution for the variation in the parameter x. When the search robustness calculation function is used, yi is sampled from the prediction distribution fhat,s(x). When the recommendation robustness calculation function is used, yi is sampled from the prediction average fhat,m(x).

Next, robustness is calculated based on the set of predicted values {yi}. The robustness is a scalar value. When the robustness is evaluated by the specification excess amount, the specification excess amount of Formula (6) is calculated as the robustness.

When the processing of step S5 in FIG. 7 ends, the optimization execution unit 6 and the optimization start point determination unit 7 optimize the search robustness calculation function based on the following Formula (15) to find a search point (start point) xs,n+1 (step S6). argmin in Formula (15) means to obtain a minimum value of the search robustness calculation function hs(fhat,s(g(x))) in parentheses.

$${x}_{s , n + 1} = {arg min}_{x ∈ 𝒳} ( {h}_{s} ( {f}_{hat , s} ( g ( x ) ) ) ) \qquad ( 15 )$$

### Optimization in Step S6

In a case where the optimization in step S6 is the minimization of the search calculation function hs(fhat,s(g(x))), the processing of the optimization start point determination unit 7 may be omitted, and the optimization execution unit 6 may perform the following processing. First, a set {xi}(i=1, . . . , and L) of L parameters x is generated in the sobol string of the quasi-random number. Next, robustness {ri}(i=1, . . . , and m) of each parameter x is calculated based on the following Formula (16).

$$ri = fhat , s ( g ( xi ) ) \qquad ( 16 )$$

Next, a parameter corresponding to a minimum value of {ri}(i=1, . . . , and L) is set as xs,n+1. In this manner, it is possible to search for an optimum point that minimizes the search calculation function hs(fhat,s(g(x))) without setting a start point.

When the processing of step S6 in FIG. 7 ends, the simulation execution unit 2 evaluates the search point xs,n+1 found in step S6 by simulation, and stores the simulation execution result y in the storage unit 10 (not illustrated) (step S7).

Next, the optimization execution unit 6 optimizes the search robustness calculation function based on the following Formula (17) to find a recommendation point xr,n+1 (step S8). argmin in Formula (17) means to obtain a minimum value of the recommendation calculation function hr(fhat,m(g(x))).

$${x}_{r , n + 1} = {arg min}_{x ∈ 𝒳} ( {h}_{r} ( {f}_{hat , m} ( g ( x ) ) ) ) \qquad ( 17 )$$

When the optimization in step S8 is the minimization of the recommendation calculation function hr(fhat,m(g(x))), the optimization start point determination unit 7 performs binary classification learning of predetermined specification satisfiability using a decision tree from the curve of the search calculation function, and outputs an average value of the parameters x of the specification satisfaction sample of the leaf having the maximum number of specification satisfiability included in the leaf of the learned decision tree as a start point for optimization.

Next, the optimization execution unit 6 repeats processing of setting a first additional start point and a second additional start point on both sides with the start point interposed therebetween on the curve of the search calculation function, setting a new start point obtained by optimizing robustness based on the start point, the first additional start point, and the second additional start point, and newly setting a first additional start point and a second additional start point on both sides of the new start point, thereby finding a recommendation point that minimizes the search calculation function.

When the processing of step S8 in FIG. 7 ends, the simulation execution unit 2 evaluates the recommendation point xr,n+1 found in step S8 by simulation, and stores the simulation execution result y in the storage unit 10 (not illustrated) (step S9).

Next, it is determined whether the simulation result in step S8 satisfies a specification and whether the number of repetitions of the simulation has reached a predetermined iteration number (step S10). The processing of steps S3 to S9 is repeated until YES is determined in step S10. When step S10 is YES, a recommendation point with the best robustness is output (step S11), and the processing ends.

The best recommendation point finally output by the flowchart in FIG. 7 is the parameter x with which the clear rate of 100% is obtained.

### (Search Processing and Recommendation Processing)

The reason why the search robustness calculation function hs(fhat,s(g(x))) and the recommendation robustness calculation function hr(fhat,m(g(x))) are generated in step S5 in FIG. 7 is as follows.

Bayesian optimization has concepts of “exploration” for collecting data of an unknown region and “exploitation” for intensively searching for a region with a good known evaluation value. When “exploitation” is performed, a possibility of improving a best value increases, but since only the same place is viewed, the possibility of greatly improving the best value decreases. On the other hand, since an unknown region is viewed in the “exploration”, it is uncertain whether the best value can be immediately improved, but potentially there is a possibility of significant improvement of the best value. Therefore, in the Bayesian optimization, determination of a next evaluation point with emphasis on uncertainty of prediction (prediction variance) is regarded as “exploration”, and determination of a next evaluation point with emphasis on an expected value of prediction (prediction average) is regarded as “exploitation”.

In the search robustness calculation function, since a simulation result is predicted by a sample from a prediction distribution, a sample value considering prediction uncertainty is generated. Therefore, it is an incentive to search for an unknown region.

In the recommendation robustness calculation function, since the simulation result is predicted by the prediction average, the next evaluation point is determined with emphasis on the expected value of prediction. This corresponds to exploitation.

Therefore, when it is necessary to determine the value of the parameter with an extremely small number of evaluations in performing the processing of step S5 in FIG. 7, only the recommendation robustness calculation function may be used. In this case, since only the processing of obtaining the recommendation point is performed, it is better to increase the possibility of improving the best value by exploitation, and thus only the recommendation robustness calculation function may be used. On the other hand, in a case where the value of the parameter can be determined by a relatively large number of evaluations, there is room for searching. Therefore, in order to significantly improve the best value, it is desirable to perform the processing of S6 to S9 in FIG. 7 by using the search robustness calculation function and the recommendation robustness calculation function in combination.

### (Learning of Worst Point)

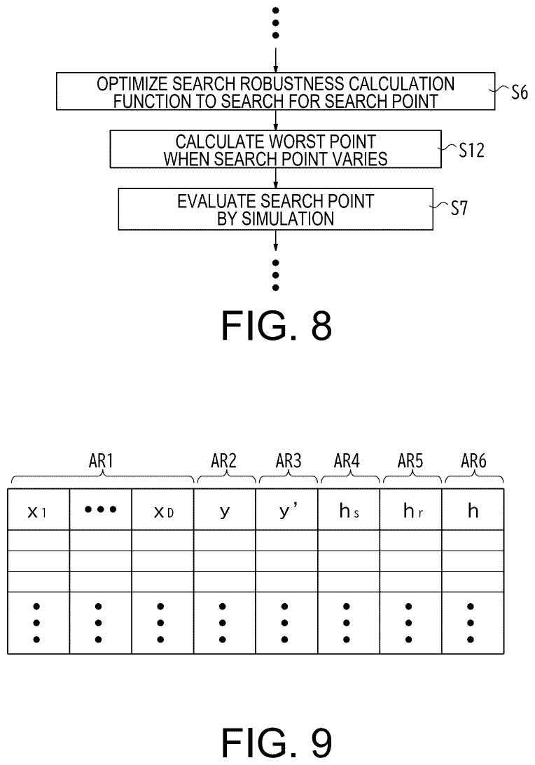

When the processing of step S6 in FIG. 7 is performed, there is a possibility that it is difficult to learn a portion having a large variation when the search point varies. Therefore, as illustrated in FIG. 8, the processing of step S12 may be provided between steps S6 and S7 in FIG. 7.

In step S12, a worst point when the search point xs,n+1 varies is calculated by the following Formula (18). argmax in Formula (18) means to obtain the maximum value of fhat,s(x).

$${x}_{s , n + 1} = {arg max}_{x ∈ g ( {x}_{s , n + 1 )} \text{?}} {f}_{hat , s} ( x ) \qquad ( 18 )$$

Set of row vectors in x∈g(x_(s,n+1))

The optimization execution unit 6 can generate a normal variation when the optimum point of the search robustness calculation function is set as the center of the normal distribution, and set the variation in the parameter x with which the simulation execution result is maximized among the variations as the search point. As a result, the worst case can be modeled, and the optimum point at which the clear rate is 100% can be found with higher accuracy.

FIG. 9 is a diagram illustrating a data configuration stored in the storage unit 10 of the information processing apparatus 1. The storage unit 10 in FIG. 9 includes a region AR1 that stores a plurality of parameters x1, . . . , and xD, a region AR2 that stores a simulation execution result y, a region AR3 that stores a converted value y′ obtained by sigmoid-converting the simulation execution result, a region AR4 that stores robustness (for example, the specification excess amount, the maximum value at the time of parameter variation, and the like) hs calculated by the search robustness calculation function, a region AR5 that stores robustness (for example, the specification excess amount, the maximum value at the time of parameter variation, and the like) hr calculated by the recommendation robustness calculation function, and a region AR6 that stores a robustness evaluation result (such as a clear rate) h. The storage unit 10 in FIG. 9 may be divided into a plurality of storage units 10.

### (Processing of Optimization Start Point Determination Unit 7)

In the Bayesian optimization, an acquisition function calculated based on the prediction model is optimized. In the optimization of the acquisition function, it is common to randomly generate a large number of parameters, and apply a gradient method with the best value among the parameters as a start point for optimization to search until the gradient becomes zero.

When the parameter exists in a high-dimensional space, it is difficult to search for an appropriate evaluation value by random search because the space is too wide, and it is easy to increase the accuracy of updating the best value by setting the best value of the already evaluated data as a start point.

In a case where robustness is optimized instead of simple minimization or maximization of the simulation execution result y, there is no appropriate method for determining the best point from the already evaluated data.

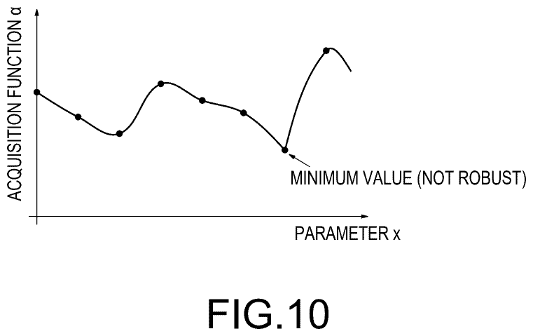

FIG. 10 is a diagram illustrating an example of an acquisition function representing robustness. As illustrated in FIG. 10, when the acquisition function rapidly changes from a certain point (for example, a minimum value), this point cannot be said to be robust. This is because the value of the acquisition function greatly changes due to the variation in the parameter x.

Therefore, the optimization start point determination unit 7 classifies data having high proximity into the same group among a plurality of pieces of data on the curve of the acquisition function, and generates a plurality of groups. Then, a group Grobust having high robustness is extracted from the plurality of groups, and a start point is determined from the extracted group Grobust.

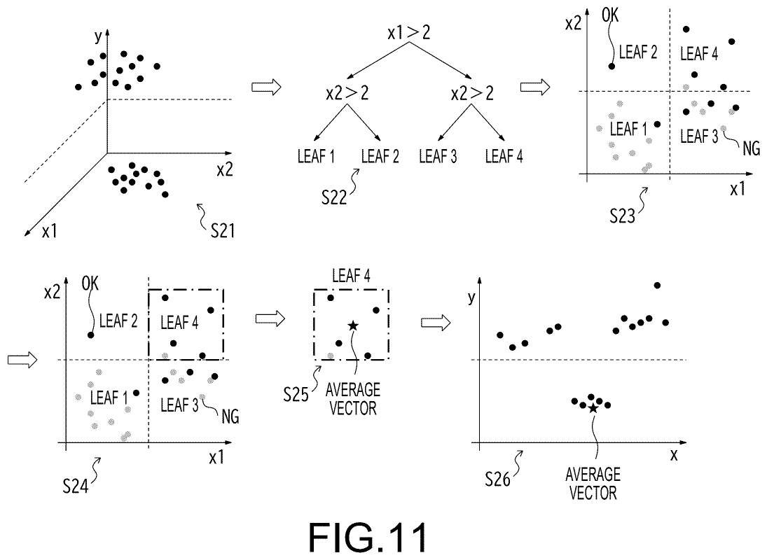

FIG. 11 is a diagram for explaining a processing operation of the optimization start point determination unit 7. First, a binary label indicating whether the specification is satisfied (OK) or not satisfied (NG) is given to each of the plurality of pieces of evaluated data (step S21). In step S21, an example is illustrated in which each parameter is distributed in a two-dimensional space X=(x1, x2).

Next, each sample is binary classified using a decision tree (step S22). Step S22 indicates an example of classifying into a plurality of leaves depending on whether the coordinates (x1, x2) of each parameter are larger than 2.

Next, the evaluated data is classified using a decision tree (step S23). Step S23 indicates an example in which each of the plurality of pieces of evaluated data is classified into one of the leaves 1 to 4.

Next, the number of OK is counted for each classified region (step S24). Step S24 indicates an example in which the number of OK is counted for each of the leaves 1 to 4.

Next, an average vector of the parameters in the region where the number of OK is the maximum is calculated (step S25). Step S25 indicates an example in which the leaf 4 is selected and an average vector of four parameters in the leaf 4 is calculated.

The reason why the region (leaf) having the maximum number of OK samples is selected in steps S24 and S25 is that the large number of OK samples means that the accuracy of robustness is high, there is sufficient room for the prediction model to learn, and it is easy to perform fine adjustment with high accuracy.

A multiplication value of the OK rate and the number of samples may be calculated in step S24, and a region (leaf) at with the multiplication value is maximum may be selected in step S25. As the OK rate is higher, the clear rate is higher, and the optimum point can be searched from a more robust region.

Next, optimization is started with the position of the average vector calculated in step S25 as a start point (step S26).

### (Processing of Optimization Execution Unit 6)

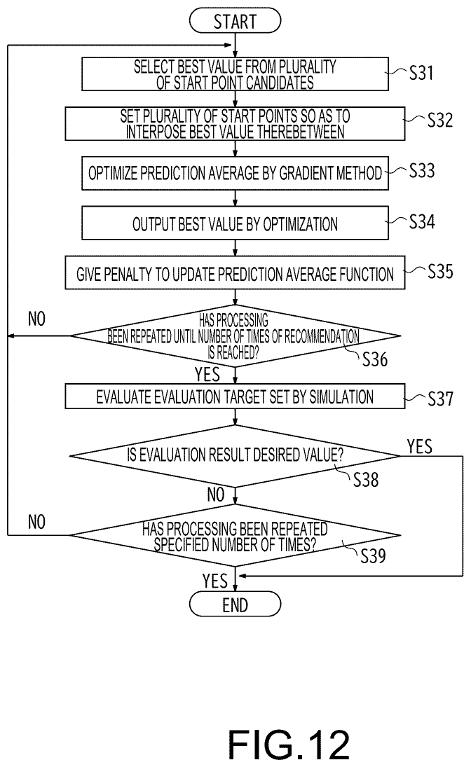

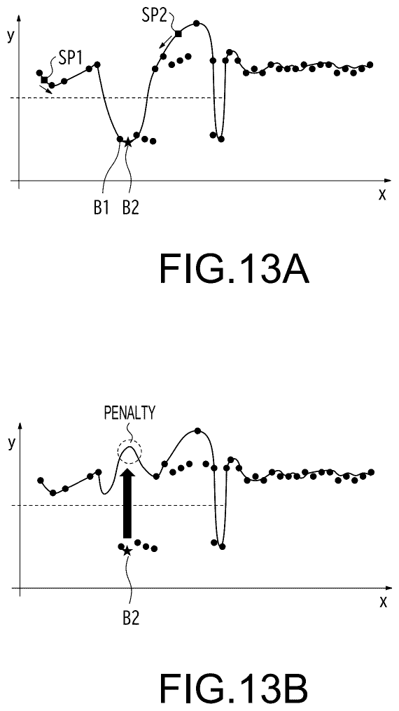

FIG. 12 is a flowchart illustrating a processing procedure of the optimization execution unit 6, and FIGS. 13A and 13B are diagrams for explaining the processing of the optimization execution unit 6. First, an initial best value B1 is selected from a plurality of start point candidates that have been evaluated or obtained based on knowledge (step S31). Next, a plurality of start points SP1 and SP2 are set so as to interpose the initial best value B1 therebetween (step S32). The plurality of start points SP1 and SP2 to be set are referred to as an evaluation target set.

Next, the prediction average is optimized by the gradient method from each of the plurality of start points SP1 and SP2 set in step S32 (step S33). Next, a best value B2 is output in the optimization of the prediction average at each of the start points SP1 and SP2 (step S34).

FIG. 13A illustrates an example in which the best value B2 is output by the processing of steps S31 to S34.

Next, in order to give a penalty to the best value B2, the prediction average function is updated (step S35). FIG. 13B illustrates an example in which the prediction average function is updated by giving a penalty to the best value B2 output in FIG. 13A.

When the processing of step S35 ends, it is determined whether the processing of steps S31 to S35 has been repeated until the number of times of recommendation is reached (step S36). When step S36 is NO, the processing of steps S31 to S35 is repeated. When step S36 is YES, the evaluation target set is evaluated by simulation (step S37). In step S37, the prediction average function is updated with Data based on the following Formula (16).

$$Data = Data + \{ ( evaluation target , evaluation result ) \} \qquad ( 16 )$$

It is determined whether the evaluation result obtained in step S37 is a desired result (step S38), and when the evaluation result is a desired result, the processing in FIG. 12 ends. When the result is not a desired result, it is determined whether the processing has been repeated a specified number of times (step S39). When the number of times has not reached the specified number of times, the processing in step S31 and subsequent steps is repeated until the specified number of times is reached. When the specified number of times has been reached, the processing in FIG. 12 ends.

### (Additional Start Point)

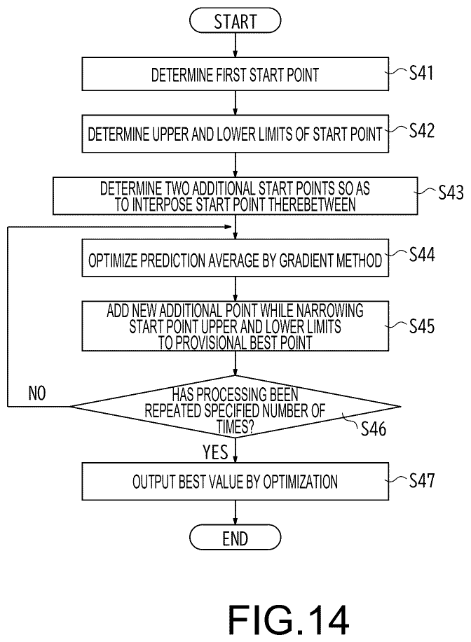

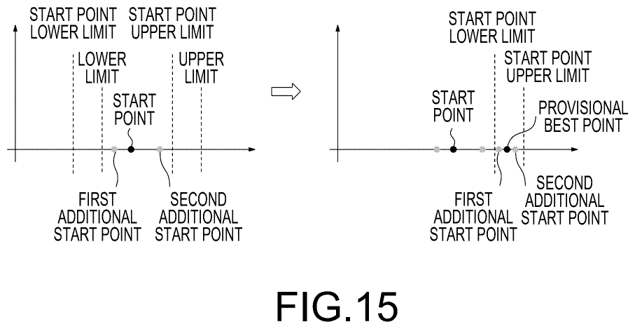

FIG. 14 is a flowchart illustrating the processing procedure of steps S32 to S34 in FIG. 12 in more detail, and FIG. 15 is a diagram for explaining the processing of the flowchart in FIG. 14. First, a first start point is determined by some method (for example, the best point of the random search) (step S41). Next, a start point upper limit and a start point lower limit are determined based on a width of an upper limit and a lower limit of the optimization with the start point as the center (step S42). Next, two additional start points are generated so as to interpose the start point in the range of the start point upper limit and the start point lower limit (step S43). In step S43, a first additional start point is generated between the start point and the start point lower limit, and a second additional start point is generated between the start point and the start point upper limit (the left side of FIG. 15).

The region protruding from the start point upper limit or the start point lower limit may be cut or may not be cut.

Next, the prediction average is optimized by the gradient method from each of the first additional start point and the second additional start point generated in step S43 (step S44).

Next, a new additional start point is added to a provisional best point while narrowing the start point upper and lower limits (step S45, right side of FIG. 15).

Next, it is determined whether the processing of steps S44 and S45 has been repeated a specified number of times (step S46). When step S46 is NO, the processing in steps S44 and S45 is repeated until the specified number of times is reached. When step S46 is YES, the best value by the optimization is output (step S47).

### (Calculation of Penalty)

Details of the calculation of the penalty in step S35 in FIG. 12 will be described below. Hereinafter, it is assumed that g(x) is a variation function, fhat,m is a prediction average of simulation execution results, fhat,σ is a prediction standard deviation of simulation execution results, and a recommendation robustness calculation function to be minimized is hr(fhat,m(g(x))).

At this time, a recommendation robustness calculation function after a penalty is applied to each of k best solutions {xj}(j=1, . . . , and k) is represented by the following Formula (19).

$${h}_{r} ( {f}_{hat , m} ( g ( x ) ) ) ← softplus ( - hr ( {f}_{hat , m} ( g ( x ) ) ) ) {\prod }_{j = 1}^{k} φ ( x ; {x}_{j} , {L}_{hat} ) \qquad ( 19 )$$

Here, softplus is represented by Formula (20), and always converts to return a positive value.

$$softplus ( z ) = In ( 1 + ez ) \qquad ( 20 )$$

The recommendation calculation function hr(fhat,m(g(x))) of Formula (19) needs to be minimized as indicated in Formula (17), but in Formula (19), the recommendation calculation function hr(fhat,m(g(x))) is multiplied by −1 to be maximized.

Lhat in Formula (19) is an estimated value of a Lipschitz coefficient of a prediction average un of the simulation execution result, and can be calculated by the following Formula (21). Note that the Lipschitz coefficient is a condition under which fluctuation of the output is suppressed to a constant multiple of fluctuation of the input.

$${L}_{hat} = {max}_{x ∈ 𝒳} ‖ {f}_{hat , {m}_{∇}} ( x ) ‖ \qquad ( 21 )$$

∥f_{hat,m}_{_{∇}}₍ₓ₎∥ is a norm of a slope f_{hat,m}_{_{∇}}₍ₓ₎ of f_{hat,m}

φ(x;xj) in Formula (19) is a local penalty function in the vicinity of xj, and can be calculated by the following Formula (22).

$$φ ( x ; {x}_{j} ) = \frac{1}{2} erfc ( - z ) , \qquad ( 22 )$$

$$where z = \frac{1}{\sqrt{2 {f}_{hat , σ} ( {x}_{j} )}} ( {L}_{hat} ‖ {x}_{j} - x ‖ - Min + {f}_{hat , m} ( {x}_{j} ) )$$

Here, efrc is a complementary error function,

$$Min = {min}_{x ∈ 𝒳} {f}_{hat , m} ( x ) .$$

efrc is a complementary error function, and

Formula (19) described above intends to maximize the function. Since the robustness calculation function according to the present embodiment is a function to be minimized, a minus sign is added to the beginning of the function hr, and is converted into a function for maximization and applied. Therefore, in Formulas (19) to (22), a maximum peak of the function is searched, and every time the peak is found, processing of collapsing the peak is performed.

As fhat,m(xj) approaches Min and as Lhat increases, −z decreases and φ approaches 1.

Since Formula (23) holds, it is easy to return the function as it is for the most part.

$$1 \times - {h}_{r} ( {f}_{hat} , ( g ( x ) ) ) = - {h}_{r} ( {f}_{hat ,} ( g ( x ) ) ) \qquad ( 23 )$$

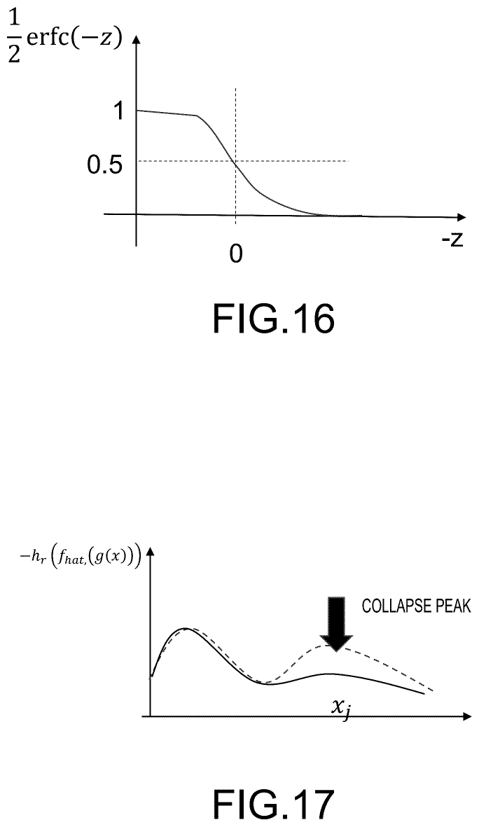

This results in a locally effective penalty. As xj is closer to x, as illustrated in FIG. 16,

$$\frac{1}{2} erfc ( - z )$$

approaches 0.5, and approaches 1 as xj is farther from x.

Therefore, a penalty is given around xj, and the peak is collapsed as illustrated in FIG. 17.

As described above, in the present embodiment, the robustness such as the specification excess amount can be easily and quickly optimized in consideration of the variation in parameter.

In addition, in the present embodiment, since the output of the prediction model is sigmoid-converted according to the specification, the output of the prediction model in the vicinity of the specification can be analyzed in detail, and the calculation accuracy of robustness can be improved.

In addition, in the present embodiment, since evaluation is performed by replacing the clear rate with robustness such as a specification excess amount, accuracy of optimization of the clear rate can be improved.

In addition, since the start point is set on the curve of the robustness calculation function and the start point is optimized, the optimization processing can be performed in consideration of the variation in parameter, and the optimization performance can be improved.

For example, as illustrated in FIGS. 2A, 2B and 2C, the information processing apparatus 1 according to the present embodiment can be applied to optimization of manufacturing conditions in which the height from the bottom surface of the trench 12 to the void 14 satisfies the specification.

At least some of the information processing apparatus 1 described in the above-described embodiment may be configured by hardware or software. In a case where the information processing apparatus 1 is configured by software, a program for implementing at least some functions of the information processing apparatus 1 may be stored in a recording medium such as a flexible disk or a CD-ROM, and may be read and executed by a computer. The recording medium is not limited to a removable recording medium such as a magnetic disk or an optical disk, and may be a fixed recording medium such as a hard disk device or a memory.

In addition, a program for implementing at least some functions of the information processing apparatus 1 may be distributed via a communication line (including wireless communication) such as the Internet. Further, the program may be distributed via a wired line or a wireless line such as the Internet or stored in a recording medium in an encrypted, modulated, or compressed state.

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fall within the scope and spirit of the disclosures.

1. An information processing apparatus comprising processing circuitry configured to:
execute simulation based on a simulation model;
manage a variation in parameter set in the simulation model;
learn a prediction model by performing regression learning based on a relationship between the parameter and a simulation execution result;
calculate robustness based on a prediction model learning result and the variation in parameter; and
optimize the robustness based on the calculated robustness, the prediction model, and the parameter.

2. The information processing apparatus according to claim 1, wherein
the processing circuitry is configured to:
assume that the variation in parameter is represented by a normal distribution, and gives the variation in the parameter within a range of standard deviation×±m (m is a real number of 1 or more) times of the normal distribution, and
learn the prediction model based on the parameter to which the variation is given.

3. The information processing apparatus according to claim 2, wherein
the processing cuircitry is configured to determine a value of the m based on a proportion of the parameter existing within the range of the normal distribution.

4. The information processing apparatus according to claim 1, wherein the processing circuitry is further configured to convert the simulation execution result according to a predetermined target range, wherein
the processing circuitry is configured to learn the prediction model based on the parameter and the converted simulation execution result.

5. The information processing apparatus according to claim 4, wherein
the processing cicuitry is configured to sigmoid-convert the simulation execution result based on the target range and a sigmoid function.

6. The information processing apparatus according to claim 5, wherein
the processing circuitry is configured to change the simulation execution result closer to the target range more greatly.

7. The information processing apparatus according to claim 5, wherein
the processing circuitry is configured to learn the prediction model by performing regression learning based on the parameter and the simulation execution result that has been sigmoid-converted.

8. The information processing apparatus according to claim 7, wherein
the processing circuitry is configured to perform Gaussian process regression based on the parameter and the simulation execution result that has been sigmoid-converted, and update a prediction average function and a prediction distribution configuring the prediction model.

9. The information processing apparatus according to claim 1, wherein
the robustness includes at least one of a proportion at which the prediction model learning result satisfies a target range, an excess amount of the prediction model learning result from the target range, a maximum value of the prediction model learning result caused by the variation in the parameter, an average value of the prediction model learning results caused by the variation in the parameter, or a difference between the maximum value and the average value.

10. The information processing apparatus according to claim 9, wherein
the the processing circuitry is configured to calculate the robustness based on a variation function for managing the variation and a prediction distribution of the simulation execution results.

11. The information processing apparatus according to claim 9, wherein
the processing circuitry is configured to calculate the robustness based on a variation function for managing the variation and a prediction average of the simulation execution results.

12. The information processing apparatus according to claim 1, wherein the processing circuitry is further configured to determine a position of a start point for optimizing the robustness, the start point being set on a curve representing the calculated robustness, wherein
the processing circuitry is configured to search for an optimum point of the robustness on the curve with the start point as a starting point.

13. The information processing apparatus according to claim 9, wherein the processing circuitry is further configured to determine a random search on a curve representing the robustness, classification using a decision tree, a maximum improvement point of the robustness, or a median value of a search range as a start point for optimization.

14. The information processing apparatus according to claim 13, wherein
the processing circuitry is configured to classify a two-dimensional space indicating a relationship between the parameter and the robustness into a plurality of regions using the decision tree, compare a number of satisfaction of the robustness satisfying the target range in each of the plurality of regions, and determine the start point from a region having a maximum number of satisfaction.

15. The information processing apparatus according to claim 10, the processing circuitry is further configured to determine a start point for optimization on a curve of a first robustness calculation function calculated based on the calculated variation function and the prediction distribution of the simulation execution results.

16. The information processing apparatus according to claim 11, wherein the processing circuitry is further configured to determine a start point for optimization on a curve of a second robustness calculation function calculated based on the calculated variation function and the prediction average of the simulation execution results.

17. The information processing apparatus according to claim 12, wherein
the processing circuitry is configured to assume that the variation in the parameter is represented by a normal distribution, and determine, as the start point, a point at which the simulation execution result is maximized or minimized in a case where an optimum point of the curve representing the robustness is set as a center of the normal distribution.

18. The information processing apparatus according to claim 12, wherein
the processing circuitry is configured to search for an optimum point that optimizes the robustness by repeating processing of setting a first additional start point and a second additional start point on both sides with the start point interposed therebetween on the curve representing the robustness, and newly setting the first additional start point and the second additional start point on both sides of a new start point obtained by optimizing the robustness based on the start point, the first additional start point, and the second additional start point.

19. The information processing apparatus according to claim 18, wherein
the processing circuitry is configured to search for the optimum point by repeating processing of performing a shape change of the curve for giving a penalty to the start point when the first additional start point and the second additional start point located on both sides with the start point interposed therebetween are set on the curve representing the robustness, and setting the new start point, the new first additional start point, and the new second additional start point with respect to the curve after the shape change.

20. An information processing method comprising:
executing simulation based on a simulation model;
managing a variation in parameter set in the simulation model;
learning a prediction model by performing regression learning based on a relationship between the parameter and a simulation execution result;
calculating robustness based on a prediction model learning result and the managed variation in the parameter; and
optimizing the robustness based on the calculated robustness, the prediction model, and the parameter.
